(19) United States
(12) Patent Application Publication
(10) Pub. No.: US 2025/0048644 A1
(43) Pub. Date: Feb. 6, 2025

(54) BACK END LINE OF MEMORY DEVICE

(71) Applicant: Taiwan Semiconductor Manufacturing Co., Ltd., Hsinchu (TW)

(72) Inventors: Shih-Yu LIAO, Hsinchu City (TW); Chung-Liang Cheng, Changhua (TW)

(73) Assignee: Taiwan Semiconductor Manufacturing Co., Ltd., Hsinchu (TW)

(21) Appl. No.: 18/582,288

(22) Filed: Feb. 20, 2024

Related U.S. Application Data
(60) Provisional application No. 63/516,887, filed on Aug. 1, 2023.

(51) Int. Cl. H10B 51/30; G11C 11/22; H01L 23/528; H01L 29/66; H01L 29/78; H10B 51/10

(52) U.S. Cl. CPC H10B 51/30; G11C 11/22; H01L 23/528; H01L 29/66795; H01L 29/785; H10B 51/10

(57) ABSTRACT

The present disclosure describes a structure with a substrate, a first interconnect region, a second interconnect region, and a memory device region. The first interconnect region is over the substrate and includes first interconnect structures. The second interconnect region is over the first interconnect region and includes second interconnect structures electrically connected to the first interconnect structures. Further, the memory device region is between the first and second interconnect regions and includes memory cells (e.g., ferroelectric random access memory (FeRAM) cells).

### CROSS-REFERENCE TO RELATED APPLICATION

This application claims the benefit of U.S. Provisional Patent Application No. 63/516,887, titled “A Novel BEOL Comparable FeRAM NAND & FeRAM NOR Device and Method,” which was filed on Aug. 1, 2023 and is incorporated herein by reference in its entirety.

### BACKGROUND

With advances in semiconductor technology, there have been increasing demands for higher storage capacity, faster processing systems, higher performance, and lower costs. To meet these demands, the semiconductor industry continues to scale down the dimensions of circuit elements, such as memory devices. As storage capacity increases and the number of circuit elements increases accordingly, the semiconductor manufacturing process becomes increasingly more complex.

### BRIEF DESCRIPTION OF THE DRAWINGS

Aspects of the present disclosure are best understood from the following detailed description when read with the accompanying figures. It is noted that, according to the standard practice in the industry, various features are not drawn to scale. In fact, the dimensions of the various features may be arbitrarily increased or reduced for clarity of discussion.

FIG. 1 is an illustration of a block-level representation of a memory system, according to some embodiments.

FIG. 2 is an illustration of a cross-sectional view of a semiconductor device that incorporates one or more elements of a memory system, according to some embodiments.

FIG. 3 is an illustration of a cross-sectional view of a portion of a semiconductor device, according to some embodiments.

FIG. 4 is an illustration of another cross-sectional view of a semiconductor device, according to some embodiments.

FIG. 5 is an illustration of a circuit representation of a portion of a memory array, according to some embodiments.

FIG. 6A is an illustration of a top-view layout representation of a portion of a memory array, according to some embodiments.

FIG. 6B is an illustration of a zoomed-in, top-view layout representation of a portion of a memory array, according to some embodiments.

FIG. 7 is an illustration of a cross-sectional view of a portion of a memory array, according to some embodiments.

FIG. 8 is an illustration of another cross-sectional view of a portion of a memory array, according to some embodiments.

FIG. 9 is an illustration of another circuit representation of a portion of a memory array, according to some embodiments.

FIG. 10A is an illustration of another top-view layout representation of a portion of a memory array, according to some embodiments.

FIG. 10B is an illustration of another zoomed-in, top-view layout representation of a portion of a memory array, according to some embodiments.

FIG. 11 is an illustration of yet another cross-sectional view of a portion of a memory array, according to some embodiments.

FIG. 12 is an illustration of a method to form a memory cell in a back end of line device memory region of a semiconductor device, according to some embodiments.

FIGS. 13-18 are illustrations of partial cross-sectional views of a memory cell in a back end of line device memory region of a semiconductor device at various stages of its fabrication process, according to some embodiments.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. In addition, the present disclosure repeats reference numerals and/or letters in the various examples. This repetition is for the purpose of simplicity and clarity and, unless indicated otherwise, does not in itself dictate a relationship between the various embodiments and/or configurations discussed. Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

With advances in semiconductor technology, there have been increasing demands for higher storage capacity, faster processing systems, higher performance, and lower costs. To meet these demands, the semiconductor industry continues to scale down the dimensions of circuit elements, such as memory devices. As storage capacity increases and the number of circuit elements increases accordingly, chip area to implement memory devices becomes more challenging.

The present disclosure describes a semiconductor device that includes memory devices (e.g., ferroelectric random access memory (FeRAM) cells) in a back end of line region (e.g., interconnect structures disposed above a substrate of the semiconductor device). The semiconductor device can include a substrate, a first interconnect region disposed over the substrate, a second interconnect region disposed over the first interconnect region, and a third interconnect region disposed over the second interconnect region. The substrate can include electrical components—e.g., active devices, passive devices, or a combination active and passive devices—formed thereon. The first interconnect region can include interconnect structures (e.g., metal line structures and metal via structures) to electrically connect the electrical components to one another and/or to upper interconnect structures (e.g., interconnect structures in the second interconnect region and in the third interconnect region). The second interconnect region can include a memory device region and interconnect structures (e.g., metal line structures and metal via structures). The memory device region can include memory cells (e.g., FeRAM cells) electrically connected to the electrical components via the interconnect structures in the first interconnect region. Each of the ferroelectric memory cells can include a ferroelectric material (e.g., hafnium zirconium oxide) disposed on a top surface and side surfaces of a fin structure (e.g., made of indium gallium zinc oxide). Further, the third interconnect region can include interconnect structures (e.g., metal line structures and metal via structures).

A benefit, among others, of implementing the memory cells in the memory device region is that the back end of line region of the semiconductor device can be utilized for the fabrication of memory cells, thus increasing storage capacity in the semiconductor device. Another benefit of implementing the memory cells in the back end of line region is that additional substrate area is available for the implementation of additional electrical components to enhance the functionality and performance of the semiconductor device.

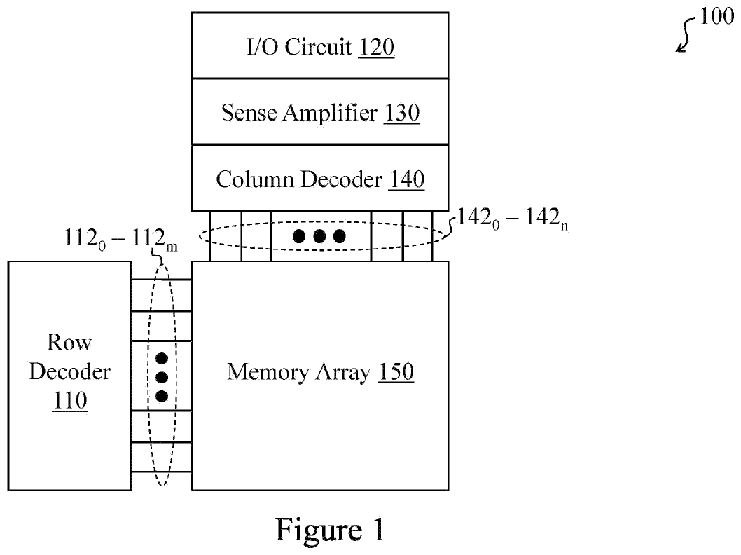

FIG. 1 is an illustration of a block-level representation of a memory system 100, according to some embodiments. In some embodiments, memory system 100 can include a row decoder 110, an input/output (I/O) circuit 120, a sense amplifier 130, a column decoder 140, and a memory array 150.

Memory array 150 includes memory cells arranged in rows and columns that are accessed—e.g., for memory read and write operations—using a memory address. In some embodiments, the memory cells in memory array 150 can be FeRAM cells. Although the description below is in the context of a memory system with FeRAM cells, other types of systems and memory cells can implement the embodiments described herein.

Based on the memory address, row decoder 110 selects a row of memory cells to access (e.g., via wordlines 112₀-112ₘ) and column decoder 140 selects a column of memory cells to access (e.g., via bitlines 142₀-142ₙ). An intersection of the selected row of memory cells and the selected column of memory cells corresponds to a selected memory cell in memory array 150 that can be accessed. Sense amplifier 130 detects whether the selected memory cell is in a conducting state or a non-conducting state—corresponding to the on/off state of the selected memory cell—during a sensing period. The on/off state of the selected memory cell can correspond to either a digital ‘0’ or a digital ‘1’, in which I/O circuit 120 provides this digital representation of the state of the selected memory cell to an external circuit (not shown in FIG. 1). Other memory operations can be performed using row decoder 110, I/O circuit 120, sense amplifier 130, column decoder 140, and memory array 150. These other memory operations are within the spirit and scope of the present disclosure.

A challenge, among other, in the design of memory system 100 is implementing memory array 150 with an increased storage capacity and thus an increased number of memory cells (e.g., FeRAM cells). For example, as system designs become more complex with increased functionality and performance, additional chip area is consumed to implement these complex designs—leaving limited chip area for additional memory cells to increase storage capacity. The present disclosure addresses these challenges, among others, by implementing memory array 150 (e.g., the entire memory array or portions thereof) in a back end of the line region (e.g., metal layers disposed above a substrate of a semiconductor device) of the chip design.

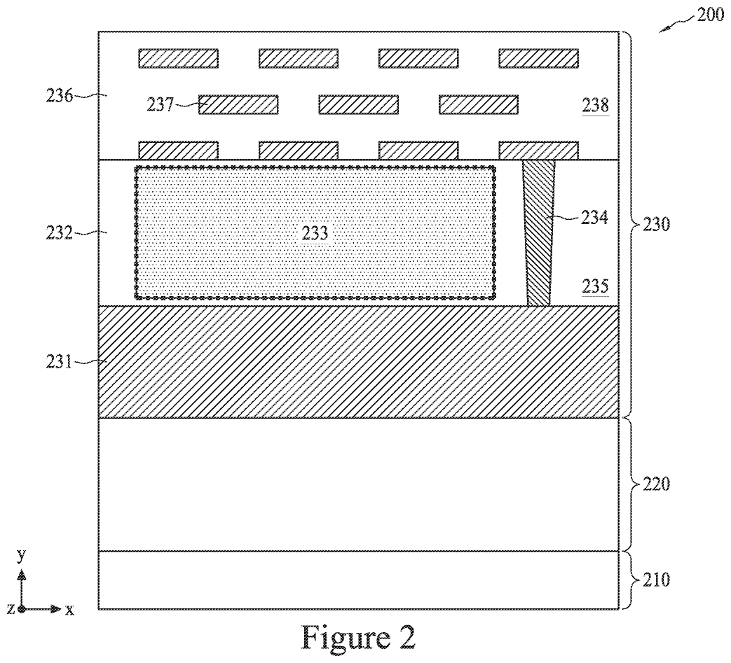

FIG. 2 is an illustration of a cross-sectional view of a semiconductor device 200 that incorporates one or more circuit elements of memory system 100, according to some embodiments. Semiconductor device 200 can include a substrate 210, a device region 220, and a back end of line region 230, according to some embodiments.

Substrate 210 can include a semiconductor material, such as crystalline silicon (Si). In some embodiments, substrate 210 can include (i) an elementary semiconductor, such as germanium (Ge); (ii) a compound semiconductor, such as silicon carbide (SiC), silicon arsenide (SiAs), gallium arsenide (GaAs), gallium phosphide (GaP), and/or a III-V semiconductor material; (iii) an alloy semiconductor, such as silicon germanium (SiGe), silicon germanium carbide (SiGeC), germanium tin (GeSn), and/or aluminum gallium arsenide (AlGaAs); (iv) a silicon-on-insulator (SOI) structure; (v) a silicon germanium (SiGe)-on insulator structure (SiGeOI); (vi) a germanium-on-insulator (GeOI) structure; or (vii) a combination thereof. Alternatively, substrate 210 can be made from an electrically non-conductive material, such as glass and a sapphire wafer. Further, substrate 210 can be doped depending on design requirements (e.g., p-type substrate or n-type substrate). In some embodiments, substrate 210 can be doped with p-type dopants (e.g., boron, indium, aluminum, or gallium) or n-type dopants (e.g., phosphorus or arsenic).

Device region 220 can be disposed on substrate 210. In some embodiments, device region 220 can include electrical components, such as active devices, passive devices, or a combination thereof. Examples of the active devices can include planar metal oxide semiconductor field effect transistors (MOSFETs), fin field effect transistors (finFETs), gate all around field effect transistors (GAAFETs), and nanostructure transistors (e.g., nanosheet transistors, nanowire transistors, multi-bridge channel transistors, and nano-ribbon transistors). Device region 220 can include one or more of these different types of active devices, which can be separated from one another using shallow trench isolation techniques, deep trench isolation, local oxidation of silicon techniques, other suitable isolation techniques, and a combination thereof. Examples of the passive devices can include resistors, capacitors, and inductors. Device region 220 can also include one or more of these different types of passive devices.

In some embodiments, device region 220 can include one or more electrical components of memory system 100 of FIG. 1. For example, device region 220 can include one or more of row decoder 110, I/O circuit 120, sense amplifier 130, and column decoder 140. In addition to the electrical components of memory system 100, device region 220 can include other types of electrical components.

Referring to FIG. 2, back end of line region 230 is disposed above device region 220 (e.g., in a y direction) and can include a first interconnect region 231, a second interconnect region 232, and a third interconnect region 236, according to some embodiments. First interconnect region 231 can include one or more interconnect structures—e.g., metal line structures and metal via structures—disposed in an interlayer dielectric structure (not shown in FIG. 2). The metal line structures and metal via structures can include copper (Cu), aluminum (Al), titanium nitride (TiN), tantalum nitride (TaN), tungsten (W), or other suitable conductive materials. The interlayer dielectric structure can include a dielectric material, such as silicon oxide (SiOₓ), silicon hydroxide (SiOH), silicon oxynitride (SiON), silicon nitride (SiNₓ), silicon oxycarbide (SiOC), silicon oxynitricarbide (SiOCN), and a combination thereof. The interlayer dielectric structure can include a stack of dielectric layers to implement multiple layers of interconnect structures.

The one or more interconnect structures in first interconnect region 231 can electrically connect to the electrical components in device region 220. For example, the one or more interconnect structures in first interconnect region 231 can electrically connect to the active devices and/or the passive devices in the electrical components of memory system 100 of FIG. 1 (e.g., row decoder 110, I/O circuit 120, sense amplifier 130, and column decoder 140) such that these electrical components can electrically connect to one another and/or to upper interconnect structures (e.g., interconnect structures in second interconnect region 232 and in third interconnect region 236).

Referring to FIG. 2, second interconnect region 232 is above first interconnect region 231 (e.g., in a y direction) and can include a memory device region 233 and a metal via structure 234—both disposed in an interlayer dielectric structure 235—according to some embodiments. Metal via structure 234 can electrically connect interconnect structures in interconnect device region 231 to interconnect structures in interconnect device region 236. Although not shown in FIG. 2, second interconnect region 232 can also include metal line structures and other metal via structures. The metal line structures and metal via structures (including metal via structure 234) can include Cu, Al, TiN, TaN, W, or other suitable conductive materials. Interlayer dielectric structure 235 can include a dielectric material, such as SiOₓ, SiOH, SiON, SiNₓ, SiOC, SiOCN, and a combination thereof. Interlayer dielectric structure 235 can include a stack of dielectric layers to implement multiple layers of interconnect structures.

In some embodiments, memory device region 233 can include one or more electrical components of memory system 100 of FIG. 1, such as memory array 150. A benefit, among others, of implementing memory array 150 in memory device region 233 is that back end of line region 230 can be utilized for the fabrication of memory cells (e.g., FeRAM cells), thus increasing storage capacity in semiconductor device 200. Another benefit of implementing memory array 150 in back end of line region 230 is that additional area in device region 220 is available for the implementation of additional electrical components to enhance the functionality and performance of semiconductor device 200.

Referring to FIG. 2, third interconnect region 236 is above second interconnect region 232 (e.g., in a y direction) and can include one or more interconnect structures disposed in an interlayer dielectric structure 238. The interconnect structures can include metal line structures 237 and metal via structures (not shown in FIG. 2). The metal line structures and metal via structures can include Cu, Al, TiN, TaN, W, or other suitable conductive materials. The interconnect structures in third interconnect region 236 can electrically connect to the electrical components in device region 220 through metal via structure 234 (and other metal via structures not shown in FIG. 2) and first interconnect region 231. Interlayer dielectric structure 238 can include a dielectric material, such as SiOₓ, SiOH, SiON, SiNₓ, SiOC, SiOCN, and a combination thereof. Interlayer dielectric structure 238 can include a stack of dielectric layers to implement multiple layers of interconnect structures. Although three layers of metal line structures 237 are shown in third interconnect region 236, third interconnect region 236 can have more or less than three metal line structures, depending on the design of semiconductor device 200.

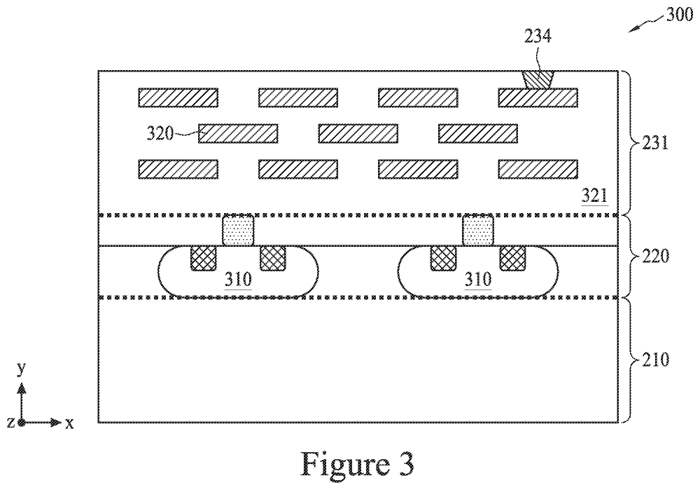

FIG. 3 is an illustration of a cross-sectional view of a portion 300 of semiconductor device 200, according to some embodiments. Portion 300 includes substrate 210, device region 220, and first interconnect region 231. Although not shown in FIG. 3, second interconnect region 232 and third interconnect region 236 are disposed above first interconnect region 231 as shown in FIG. 2.

Device region 220 can include active devices 310 implemented within and/or on substrate 210. Active devices 310 can include one or more of planar MOSFETs, finFETs, GAAFETs, and nanostructure transistors (e.g., nanosheet transistors, nanowire transistors, multi-bridge channel transistors, and nano-ribbon transistors), according to some embodiments. Active devices 310 can be separated from one another using shallow trench isolation techniques, deep trench isolation, local oxidation of silicon techniques, other suitable isolation techniques, and a combination thereof. In some embodiments, active devices 310 can represent one or more of the electrical components in memory system 100 of FIG. 1 (e.g., row decoder 110, I/O circuit 120, sense amplifier 130, and column decoder 140). In some embodiments, active devices 310 can represent one or more electrical components of memory system 100, another system, or a combination of both systems. Further, although not shown in FIG. 3, device region 220 can also include passive devices (e.g., resistors, capacitors, and inductors) implemented within and/or on substrate 210.

In some embodiments, first interconnect region 231 can include interconnect structures—e.g., metal line structures 320 and metal via structure 234—disposed in interlayer dielectric structure 321. Metal line structures 320 and metal via structure 234 can electrically connect to the active devices and/or the passive devices in device region 220 (e.g., active devices 310) such that these electrical components can electrically connect to one another and/or to upper interconnect structures (e.g., interconnect structures in second interconnect region 232 and in third interconnect region 236—not shown in FIG. 3). Although not shown in FIG. 3, first interconnect region 231 can also include other metal via structures. The metal line structures and metal via structures (including metal via structure 234) can include Cu, Al, TiN, TaN, W, or other suitable conductive materials. Interlayer dielectric structure 321 can include a dielectric material, such as SiOₓ, SiOH, SiON, SiNₓ, SiOC, SiOCN, and a combination thereof. Interlayer dielectric structure 321 can include a stack of dielectric layers to implement multiple layers of interconnect structures.

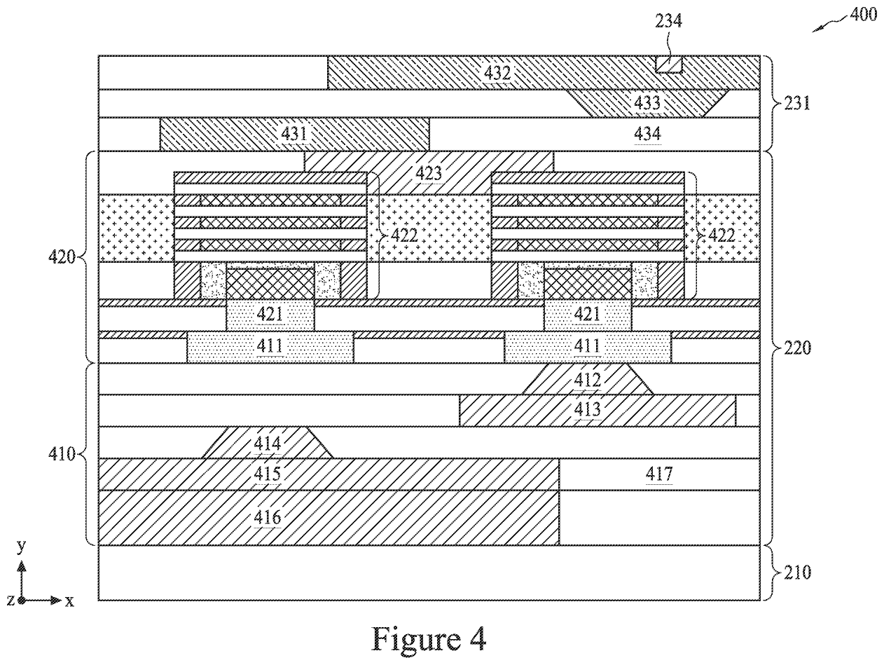

FIG. 4 is an illustration of another cross-sectional view of a portion 400 of semiconductor device 200, according to some embodiments. Although not shown in FIG. 4, second interconnect region 232 and third interconnect region 236 are disposed above first interconnect region 231 as shown in FIG. 2.

Portion 400 includes substrate 210, device region 220, and first interconnect region 231. Device region 220 can include a backside interconnect region 410 and device region 420, according to some embodiments. In some embodiments, backside interconnect region 410 is below device region 220 (e.g., in a y direction). Backside interconnect region 410 can include interconnect structures (e.g., as part of a redistribution layer network of interconnect structures) disposed in an interlayer dielectric structure 417 and arranged to provide a power supply voltage to electrical components in device region 420. Interlayer dielectric structure 417 can include a dielectric material, such as SiOₓ, SiOH, SiON, SiNₓ, SiOC, SiOCN, and a combination thereof. Interlayer dielectric structure 417 can include a stack of dielectric layers to implement multiple layers of interconnect structures. Further, the interconnect structures can include metal line structures 413, 415, and 416 and metal via structures 412 and 414 electrically connected to one another and to a power supply source to provide the power supply voltage to device region 420. Metal line structures 413, 415, and 416 and metal via structures 412 and 414 can include Cu, Al, TiN, TaN, W, or other suitable conductive materials.

Device region 420 can include active devices 422 disposed above substrate 210 (e.g., in a y direction), according to some embodiments. In some embodiments, as shown in FIG. 4, active devices 422 can be GAAFETs electrically connected to backside interconnect region 410 and to first interconnect region 231 through metal contact structures 421, metal contact structure 423, and metal line structures 411. In some embodiments, active devices 422 can receive—through metal contact structures 421 and metal line structures 411—a power supply voltage from the interconnect structures in backside interconnect region 410. Further, in some embodiments, active devices 422 can receive—through metal contact structure 423—a voltage from interconnect structures in first interconnect region 231. Metal contact structures 421 and 423 and metal line structures 411 can include Cu, Al, TiN, TaN, W, or other suitable conductive materials.

In some embodiments, the power supply voltage provided to device region 220 through backside interconnect region 410 is different from a power supply voltage provided to memory device region 233 of FIG. 2. For example, referring to FIGS. 2 and 4, the power supply voltage provided to active devices 422 in device region 220 can require a higher power supply voltage than that required by memory cells (e.g., FeRAM cells) in memory device region 233. In some embodiments, the power supply voltage to device region 220 can be provided by backside interconnect region 410 and the power supply voltage to memory device region 233 can be provided by a power supply source electrically connected to second interconnect region 232—which includes interconnect structures electrically connected to memory device region 233.

Referring to FIG. 4, active devices 422 can be other types of devices, such as planar MOSFETs, finFETs, nanostructure transistors (e.g., nanosheet transistors, nanowire transistors, multi-bridge channel transistors, and nano-ribbon transistors), and a combination thereof, according to some embodiments. Active devices 422 can be separated from one another using shallow trench isolation techniques, deep trench isolation, local oxidation of silicon techniques, other suitable isolation techniques, and a combination thereof. In some embodiments, active devices 422 can represent one or more of the electrical components in memory system 100 of FIG. 1 (e.g., row decoder 110, I/O circuit 120, sense amplifier 130, and column decoder 140). In some embodiments, active devices 422 can represent one or more electrical components of memory system 100, another system, or a combination of both systems. Further, although not shown in FIG. 4, device region 220 can also include passive devices (e.g., resistors, capacitors, and inductors).

In some embodiments, first interconnect region 231 can include interconnect structures—e.g., metal line structures 431 and 432 and metal via structures 234 and 433—disposed in interlayer dielectric structure 434. Metal line structures 431 and 432 and metal via structures 234 and 433 can electrically connect to the active devices and/or the passive devices in device region 220 (e.g., active devices 422) such that these electrical components can electrically connect to one another and/or to upper interconnect structures (e.g., interconnect structures in second interconnect region 232 and in third interconnect region 236—not shown in FIG. 4). The metal line structures and metal via structures can include Cu, Al, TiN, TaN, W, or other suitable conductive materials. Interlayer dielectric structure 434 can include a dielectric material, such as SiOₓ, SiOH, SiON, SiNₓ, SiOC, SiOCN, and a combination thereof. Interlayer dielectric structure 434 can include a stack of dielectric layers to implement multiple layers of interconnect structures.

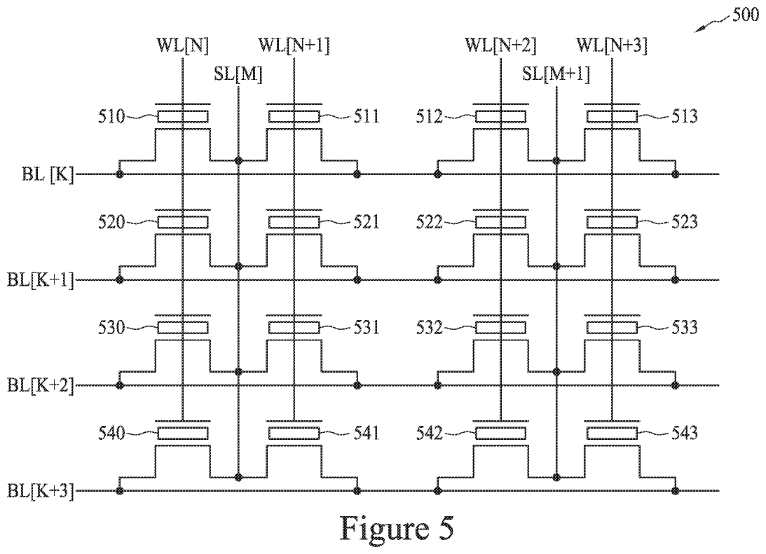

FIG. 5 is an illustration of a circuit representation of a portion 500 of memory array 150, according to some embodiments. In some embodiments, portion 500 can be disposed in memory device region 233 of FIG. 2. Referring to FIG. 5, portion 500 includes the following elements: a first NOR string arrangement including FeRAM cells 510, 511, 512, and 513 electrically connected to one another along a first bitline (e.g., BL[K], where ‘K’ is an integer equal to or greater than zero); a second NOR string arrangement including FeRAM cells 520, 521, 522, and 523 electrically connected to one another along a second bitline (e.g., BL[K+1]); a third NOR string arrangement including FeRAM cells 530, 531, 532, and 533 electrically connected to one another along a third bitline (e.g., BL[K+2]); and a fourth NOR string arrangement including FeRAM cells 540, 541, 542, and 543 electrically connected to one another along a fourth bitline (e.g., BL[K+3]). Referring to FIGS. 1 and 2, the bitlines BL[K], BL[K+1], BL[K+2], and BL[K+3] of portion 500 in memory array 150 can be electrically connected to column decoder 140. In some embodiments, column decoder 140 can be disposed in device region 220 and electrically connected—through interconnect structures in first interconnect region 231—to FeRAM cells 510-513, 520-523, 530-533, and 540-543 in the first, second, third, and fourth NOR string arrangements of memory array 150 in memory device region 233.

Referring to FIG. 5, portion 500 includes source lines SL[M] and SL[M+1]—where ‘M’ is an integer equal to or greater than zero—electrically connected to common source terminals of the FeRAM cells. Source line SL[M] is electrically connected to common source terminals of FeRAM cells 510, 511, 520, 521, 530, 531, 540, and 541. Source line SL[M+1] is electrically connected to common source terminals of FeRAM cells 512, 513, 522, 523, 532, 533, 542, and 543. In some embodiments, source lines SL[M] and SL[M+1] are electrically connected to a reference voltage supply, such as ground (e.g., 0 V).

Referring to FIG. 5, portion 500 also includes wordlines WL[N], WL[N+1], WL[N+2], and WL[N+3]—where ‘N’ is an integer equal to or greater than zero. Wordline WL[N] is electrically connected to gate terminals of FeRAM cells 510, 520, 530, and 540. Wordline WL[N+1] is electrically connected to gate terminals of FeRAM cells 511, 521, 531, and 541. Wordline WL[N+2] is electrically connected to gate terminals of FeRAM cells 512, 522, 532, and 542. And wordline WL[N+3] is electrically connected to gate terminals of FeRAM cells 513, 523, 533, and 543. Referring to FIGS. 1 and 2, the wordlines WL[N], WL[N+1], WL[N+2], and WL[N+3] to memory array 150 can be electrically connected to row decoder 110. In some embodiments, row decoder 110 can be disposed in device region 220 and electrically connected—through interconnect structures in first interconnect region 231—to the FeRAM cells in the first, second, third, and fourth NOR string arrangements of memory array 150 in memory device region 233.

Based on the description herein, portion 500 can include more or less than four FeRAM cells for each NOR string arrangement and more or less than four NOR string arrangements for memory array 150. These alternative memory array 150 arrangements are within the scope of the present disclosure.

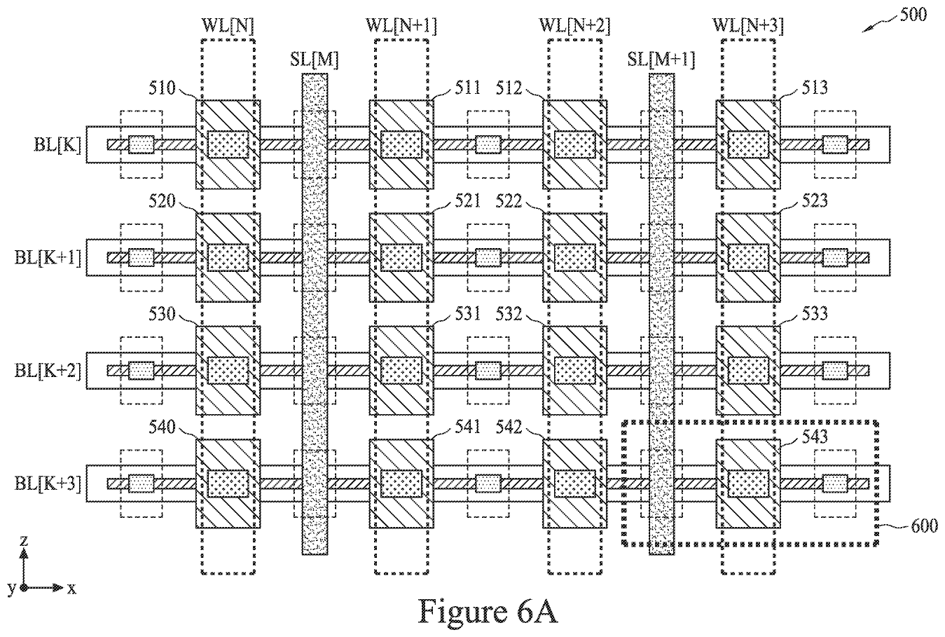

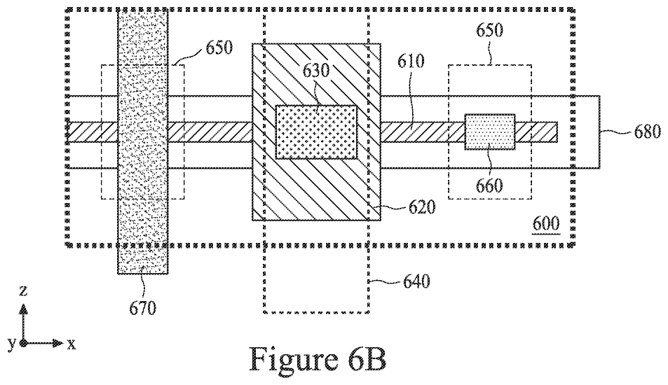

FIG. 6A is an illustration of a top-view layout representation of portion 500 of memory array 150, according to some embodiments. Due to the repetitive pattern of the FeRAM cells in portion 500, a subsection 600 of the layout representation will be described. The description of subsection 600 applies to the remainder of memory array 150. For case of illustration, FIG. 6B shows a zoomed-in view of subsection 600.

In some embodiments, subsection 600 includes a fin structure 610, a gate structure 620, a gate contact structure 630, a first metal line structure 640, source/drain contact structures 650, a metal via structure 660, a second metal line structure 670, and a third metal line structure 680. In some embodiments, fin structure 610 is formed along a first direction (e.g., an x direction) and can include indium gallium zinc oxide or other suitable materials. Gate structure 620 is formed along a second direction (e.g., a z direction; a direction perpendicular to the first direction) and is formed over fin structure 610. In some embodiments, gate structure 620 can include polysilicon, Si, Ti, Ta, Al, W, nitrogen (N), zinc (Zn), indium (In), Ga, Ge, carbon (C), or other suitable materials. In some embodiments, gate structure 620 can include TiN. Gate contact structure 630 is disposed on gate structure 620. Further, first metal line structure 640 (e.g., WL[N+3]) is formed along the second direction (e.g., a z direction) and is formed on gate contact structure 630. Gate contact structure 630 and first metal line structure 640 can include Cu, Al, TiN, TaN, W, or other suitable conductive materials.

Further, referring to FIG. 6B, source/drain contact structures 650 are formed adjacent (e.g., in an x direction) to gate structure 620. Second metal line structure 670 (e.g., SL[M+1]) is disposed on one of source/drain contact structures 650. Metal via structure 660 is disposed on the other source/drain contact structure 650. Third metal line structure 680 is disposed on metal via structure 660. In some embodiments, second metal line structure 670 (e.g., SL[M+1]) and first metal line structure 640 (e.g., WL[N+3]) can be disposed in the same metallization layer (e.g., metallization layer [X]) and third metal line structure 680 can be disposed in the next higher metallization layer (e.g., metallization layer [X+1]). Source/drain contact structures 650, metal via structure 660, second metal line structure 670, and third metal line structure 680 can include Cu, Al, TiN, TaN, W, or other suitable conductive materials.

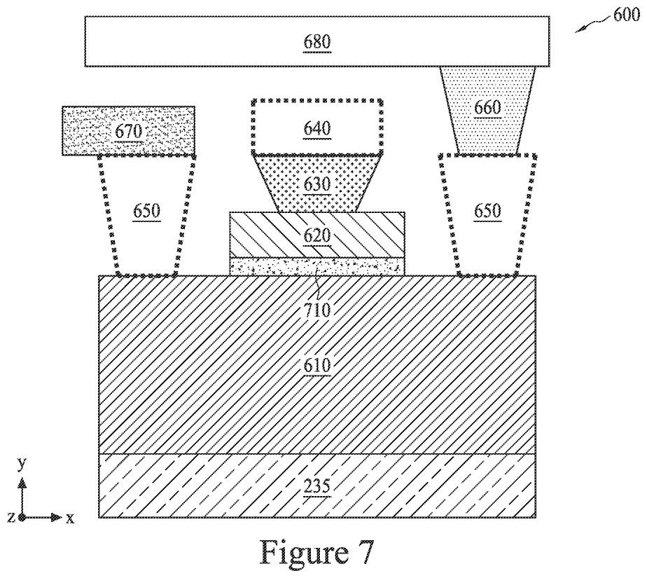

FIG. 7 is an illustration of a cross-sectional view of subsection 600 in memory array 150, according to some embodiments. This cross-sectional view is along an x direction and shows interlayer dielectric structure 235, fin structure 610, gate structure 620, gate contact structure 630, first metal line structure 640 (e.g., WL[N+3]), source/drain contact structures 650, metal via structure 660, second metal line structure 670, third metal line structure 680, and a ferroelectric material layer 710. Elements in FIG. 7 with the same annotations as elements in FIGS. 2 and 6 are described above.

Referring to FIG. 7, fin structure 610 is disposed on interlayer dielectric structure 235. In some embodiments, fin structure 610 can provide an n-type channel to the FeRAM cell. As discussed above, with respect to FIG. 2, interlayer dielectric structure 235 can include a dielectric material (e.g., SiOₓ, SiOH, SiON, SiNₓ, SiOC, SiOCN, and a combination thereof) and can include a stack of dielectric layers to implement multiple layers of interconnect structures. Here, rather than form multiple layers of interconnect structures on this portion of interlayer dielectric structure 235, a FeRAM cell (e.g., FeRAM cells 510-513, 520-523, 530-533, and 540-543 of FIG. 5) is formed.

In some embodiments, to form the FeRAM cell, ferroelectric material layer 710 is disposed on fin structure 610. Ferroelectric material layer 710 can include hafnium zirconium oxide with a zirconium percentage between about 30% and about 60%, according to some embodiments. In some embodiments, ferroelectric material layer 710 can be lead zirconate titanate (PbZrTiO), lead zirconate (PbZrO₃), lead titanate (PbTiO₃), barium titanate (BaTiO₃), lead niobate (PbNbO), bismuth titanate (BiTiO), lithium niobate (LiNbO₃), lithium tantalate (LiTaO₃), or any other suitable material. Gate structure 620 is disposed on ferroelectric material layer 710 and source/drain contact structures 650 are disposed adjacent (e.g., in an x direction) to gate structure 620, in which gate structure 620 forms a gate terminal of the FeRAM cell and source/drain contact structures 650 electrically connect to source/drain regions of the FeRAM cell, according to some embodiments. Source/drain region(s) may refer to a source or a drain, individually or collectively, depending on the context. In some embodiments, when the FeRAM cell conducts current based on the voltages applied to the gate terminal and the source/drain regions of the FeRAM cell, electrons can flow through fin structure 610 (e.g., an n-type channel) between the source/drain regions. Through gate contact structure 630, first metal line structure 640, metal via structure 660, and second metal line structure 670, gate and source/drain voltages can be provided to the FeRAM cells to perform a memory read operation, a memory write operation, and other memory operations.

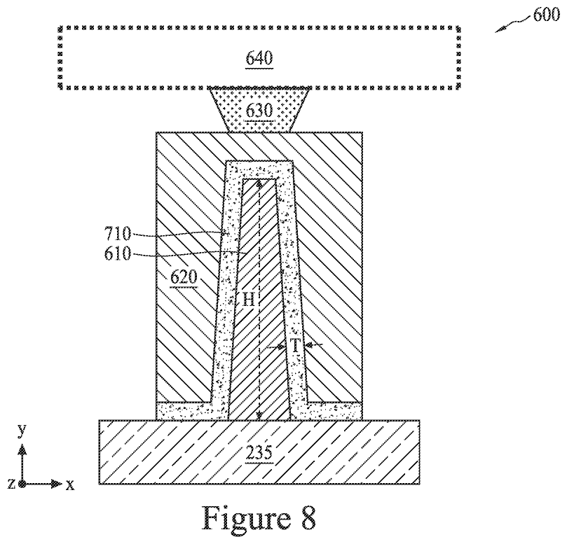

FIG. 8 is an illustration of another cross-sectional view of subsection 600 in memory array 150, according to some embodiments. This cross-sectional view is along a y direction and shows interlayer dielectric structure 235, fin structure 610, gate structure 620, gate contact structure 630, first metal line structure 640 (e.g., WL[N+3]), and ferroelectric material layer 710. Elements in FIG. 8 with the same annotations as elements in FIGS. 2, 6A, 6B, and 7 are described above.

Referring to FIG. 8, fin structure 610 can have a height H (e.g., in a y direction) between about 50 nm and about 1000 nm, according to some embodiments. In some embodiments, if height H is less than about 50 nm, a saturation current (Iₛₐₜ) of the device (with fin structure 610) may not be suitable for device application. In some embodiments, if height H is greater than about 1000 nm, fin structure 610 may collapse. In some embodiments, a thickness T of ferroelectric material layer 710 (e.g., hafnium zirconium oxide) along a top surface and side surfaces of fin structure 610 is greater than about 3 nm and has an orthorhombic phase. In some embodiments, if thickness T is less than about 3 nm, hafnium zirconium oxide may not have an orthorhombic phase and ferroelectric properties—which are desirable for ferroelectric material layer 710.

In some embodiments, to address reliability concerns due to higher voltages (e.g., about 5 V and greater) being applied to ferroelectric material layer 710 during various memory operations (e.g., a program memory operation), ferroelectric material layer 710 can have three layers: a first protection layer in contact with a top surface and side surfaces of fin structure 610; a middle ferroelectric material layer (e.g., hafnium zirconium oxide) in contact with a top surface and side surfaces of the first protection layer; and a second protection layer in contact with a top surface and side surfaces of the middle ferroelectric material layer. In some embodiments, each of the first protection layer and the second protection layer can have a thickness between about 1 nm and about 2 nm. To reduce leakage in the FeRAM cell, each of the first protection layer and the second protection layer can have between about 1% and about 2% doping of zirconium, according to some embodiments. Further, the first protection layer and the second protection layer can each include hafnium oxide (HfO₂), hafnium aluminum oxide (HfAlOx), hafnium silicate (HfSiOx), or other suitable materials—where the first protection layer can include the same material as or a different material from the second protection layer—according to some embodiments.

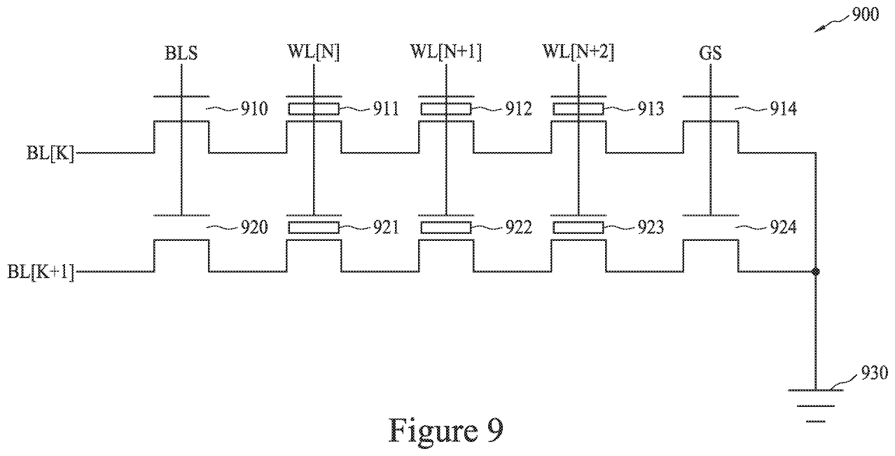

FIG. 9 is an illustration of a circuit representation of a portion 900 of memory array 150, according to some embodiments. In some embodiments, portion 900 can be disposed in memory device region 233 of FIG. 2. Referring to FIG. 9, portion 900 includes the following elements: a first NAND string arrangement including a bitline select transistor 910, FeRAM cells 911, 912, and 913, and a ground select transistor 914; and a second NAND string arrangement including a bitline select transistor 920, FeRAM cells 921, 922, and 923, and a ground select transistor 924. In the first NAND string arrangement, a source/drain terminal of bitline select transistor 910 is electrically connected to a first bitline (e.g., BL[K], where ‘K’ is an integer equal to or greater than zero). In the second NAND string arrangement, a source/drain terminal of bitline select transistor 920 is electrically connected to a second bitline (e.g., BL[K+1]). Referring to FIGS. 1 and 2, the bitlines BL[K] and BL[K+1] of portion 900 in memory array 150 can be electrically connected to column decoder 140. In some embodiments, column decoder 140 can be disposed in device region 220 and electrically connected—through interconnect structures in first interconnect region 231—to FeRAM cells 911-913 and 921-923 in the first and second NAND string arrangements of memory array 150 in memory device region 233.

Referring to FIG. 9, portion 900 includes bitline select line BLS and ground select line GS. In some embodiments, bitline select line BLS activates bitline select transistors 910 and 920 to enable the first and second NAND string arrangements. In some embodiments, ground select line GS activates ground select transistors 914 and 924 to electrically connect the first and second NAND string arrangements to a reference voltage supply 930, such as ground (e.g., 0 V).

Referring to FIG. 9, portion 900 also includes wordlines WL[N], WL[N+1], and WL[N+2]—where ‘N’ is an integer equal to or greater than zero. Wordline WL[N] is electrically connected to gate terminals of FeRAM cells 911 and 921. Wordline WL[N+1] is electrically connected to gate terminals of FeRAM cells 912 and 922. And wordline WL[N+2] is electrically connected to gate terminals of FeRAM cells 913 and 923. Referring to FIGS. 1 and 2, the wordlines WL[N], WL[N+1], and WL[N+2] in memory array 150 can be electrically connected to row decoder 110. In some embodiments, row decoder 110 can be disposed in device region 220 and electrically connected—through interconnect structures in first interconnect region 231—to the FeRAM cells in the first and second NAND string arrangements of memory array 150 in memory device region 233.

Based on the description herein, portion 900 can include more or less than three FeRAM cells for each NAND string arrangement and more or less than two NAND string arrangements for memory array 150. These alternative memory array 150 arrangements are within the scope of the present disclosure.

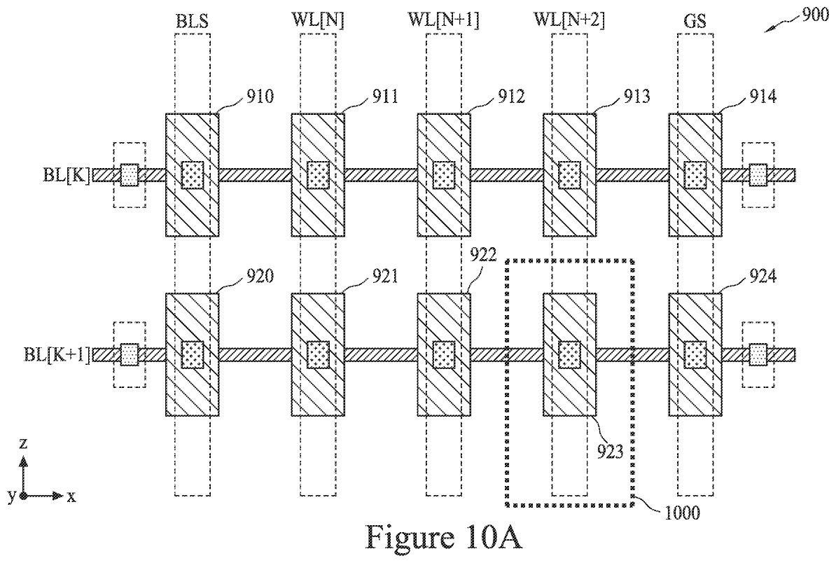

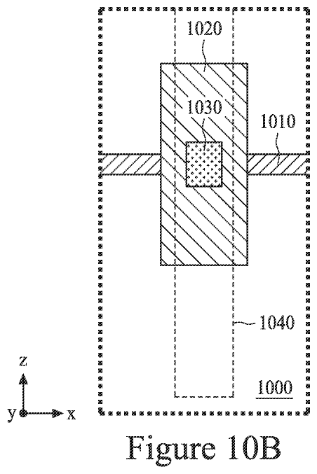

FIG. 10A is an illustration of a top-view layout representation of portion 900 of memory array 150, according to some embodiments. Due to the repetitive pattern of the FeRAM cells in portion 900, a subsection 1000 of the layout representation will be described. The description of subsection 1000 applies to the remainder of memory array 150. For case of illustration, FIG. 10B shows a zoomed-in view of subsection 1000.

In some embodiments, subsection 1000 includes a fin structure 1010, a gate structure 1020, a gate contact structure 1030, and a metal line structure 1040. In some embodiments, fin structure 1010 is formed along a first direction (e.g., an x direction) and can include indium gallium zinc oxide or other suitable materials. Gate structure 1020 is formed along a second direction (e.g., a z direction; a direction perpendicular to the first direction) and is formed over fin structure 1010. In some embodiments, gate structure 1020 can include polysilicon, Si, Ti, Ta, Al, W, N, Zn, In, Ga, Ge, C, or other suitable materials. In some embodiments, gate structure 1020 can include TiN. Gate contact structure 1030 is disposed on gate structure 1020. Further, metal line structure 1040 (e.g., WL[N+2]) is formed along the second direction (e.g., a z direction) and is formed on gate contact structure 1030. Gate contact structure 1030 and metal line structure 1040 can include Cu, Al, TiN, TaN, W, or other suitable conductive materials.

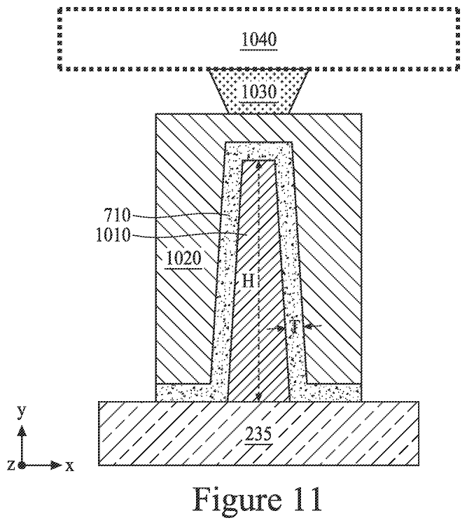

FIG. 11 is an illustration of a cross-sectional view of subsection 1000 in memory array 150, according to some embodiments. This cross-sectional view is along a y direction and shows interlayer dielectric structure 235, fin structure 1010, gate structure 1020, gate contact structure 1030, metal line structure 1040 (e.g., WL[N+2]), and ferroelectric material layer 710. Elements in FIG. 11 with the same annotations as elements in FIGS. 2, 7, 8, 10A, and 10B are described above.

Referring to FIG. 11, fin structure 1010 can have a height H (e.g., in a y direction) between about 50 nm and about 1000 nm, according to some embodiments. In some embodiments, if height H is less than about 50 nm, a saturation current (Iₛₐₜ) of the device (with fin structure 1010) may not be suitable for device application. In some embodiments, if height H is greater than about 1000 nm, fin structure 1010 may collapse. In some embodiments, fin structure 1010 can provide an n-type channel to the FeRAM cell. In some embodiments, a thickness T of ferroelectric material layer 710 (e.g., hafnium zirconium oxide) along a top surface and side surfaces of fin structure 610 is greater than about 3 nm and has an orthorhombic phase. In some embodiments, if thickness T is less than about 3 nm, hafnium zirconium oxide may not have an orthorhombic phase and ferroelectric properties—which are desirable for ferroelectric material layer 710.

In some embodiments, to address reliability concerns due to higher voltages (e.g., about 5 V and greater) being applied to ferroelectric material layer 710 during various memory operations (e.g., a program memory operation), ferroelectric material layer 710 can have three layers: a first protection layer in contact with a top surface and side surfaces of fin structure 1010; a middle ferroelectric material layer (e.g., hafnium zirconium oxide) in contact with a top surface and side surfaces of the first protection layer; and a second protection layer in contact with a top surface and side surfaces of the middle ferroelectric material layer. In some embodiments, each of the first protection layer and the second protection layer can have a thickness between about 1 nm and about 2 nm. To reduce leakage in the FeRAM cell, each of the first protection layer and the second protection layer can have between about 1% and about 2% doping of zirconium, according to some embodiments. Further, the first protection layer and the second protection layer can each include HfO₂, HfAlOx, HfSiOx, or other suitable materials—where the first protection layer can include the same material as or a different material from the second protection layer—according to some embodiments.

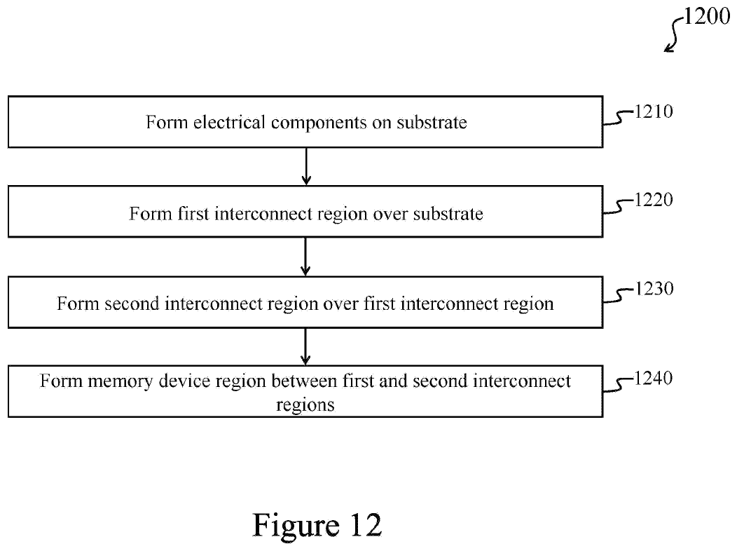

FIG. 12 is an illustration of a method 1200 to form a memory cell in a back end of line device memory region of a semiconductor device, according to some embodiments. Additional operations may be performed between various operations of method 1200 and may be omitted merely for clarity and case of description. Additional operations can be provided before, during, and/or after method 1200; one or more of these additional operations are briefly described herein. Moreover, not all operations may be needed to perform the disclosure provided herein. Additionally, some of the operations may be performed simultaneously or in a different order than shown in FIG. 12. In some embodiments, one or more other operations may be performed in addition to or in place of the presently described operations.

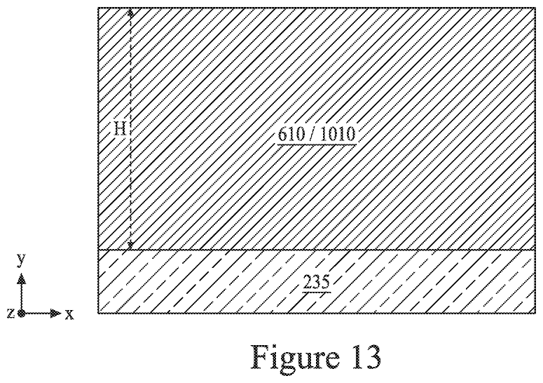

For illustrative purposes, the operations illustrated in FIG. 12 will be described with reference to an example fabrication process for forming a memory cell in memory device region 233 of second interconnect region 232 in FIGS. 2-5, 6A, 6B, 7-9, 10A, 10B, and 11. FIGS. 13-18 illustrate partial cross-sectional views of the memory cell at various stages of its fabrication process, according to some embodiments. Elements in FIGS. 13-18 with the same annotations as elements in FIGS. 1-5, 6A, 6B, 7-9, 10A, 10B, and 11 are described above.

Referring to FIG. 12, at operation 1210, one or more electrical components are formed on a substrate. For example, referring to FIGS. 3 and 4, device region 220 can be formed on substrate 210. Referring to FIG. 3, device region 220 can include active devices 310 (e.g., planar MOSFETs, finFETs, GAAFETs, and nanostructure transistors) implemented within and/or on substrate 210. Referring to FIG. 4, device region 220 can include a backside interconnect region 410 and device region 420. Backside interconnect region 410 can include interconnect structures (e.g., as part of a redistribution layer network of interconnect structures) disposed in interlayer dielectric structure 417 and arranged to provide a power supply voltage to electrical components in device region 420. Device region 420 can include active devices 422 (e.g., planar MOSFETs, finFETs, GAAFETs, and nanostructure transistors) disposed above substrate 210 (e.g., in a y direction). Although not shown in FIGS. 3 and 4, device region 220 can also include passive devices (e.g., resistors, capacitors, and inductors).

Referring to FIG. 12, at operation 1220, a first interconnect region is formed over the substrate. The first interconnect region includes first interconnect structures electrically connected to the one or more electrical components. For example, referring to FIGS. 3 and 4, first interconnect region 231 is formed over substrate 210. Referring to FIG. 3, first interconnect region 231 can include interconnect structures—e.g., metal line structures 320 and metal via structure 234—disposed in interlayer dielectric structure 321. Metal line structures 320 and metal via structure 234 can electrically connect to the active devices and/or the passive devices in device region 220 (e.g., active devices 310) such that these electrical components can electrically connect to one another and/or to upper interconnect structures (e.g., interconnect structures in second interconnect region 232 and in third interconnect region 236—not shown in FIG. 3). Referring to FIG. 4, first interconnect region 231 can include interconnect structures—e.g., metal line structures 431 and 432 and metal via structures 234 and 433—disposed in interlayer dielectric structure 434. Metal line structures 431 and 432 and metal via structures 234 and 433 can electrically connect to the active devices and/or the passive devices in device region 220 (e.g., active devices 422) such that these electrical components can electrically connect to one another and/or to upper interconnect structures (e.g., interconnect structures in second interconnect region 232 and in third interconnect region 236—not shown in FIG. 4).

Referring to FIG. 12, at operation 1230, a second interconnect region is formed over the first interconnect region. The second interconnect region includes second interconnect structures electrically connected to the first interconnect structures. For example, referring to FIG. 2, third interconnect region 236 is above first interconnect region 231 (e.g., in a y direction) and can include one or more interconnect structures disposed in interlayer dielectric structure 238. The interconnect structures can include metal line structures 237 and metal via structures (not shown in FIG. 2).

Referring to FIG. 12, at operation 1240, a memory device region is formed between the first and second interconnect regions. The memory device region includes ferroelectric memory cells. Referring to FIG. 2, memory device region 233 is formed between first interconnect region 231 and third interconnect region 236. In some embodiments, memory device region 233 can include one or more electrical components of memory system 100 of FIG. 1, such as memory array 150. In some embodiments, memory array 150 can include ferroelectric memory cells.

The formation of a memory cell (e.g., a ferroelectric memory cell) in memory device region 233 is described with respect to FIGS. 13-18. Though FIGS. 13-18 show partial cross-sectional views of a single memory cell at various stages of its fabrication process, the following description is also applicable to the formation of multiple memory cells in memory array 150 of FIG. 1—such as memory cells in a NOR string arrangement (e.g., portion 500 of memory array 150 in FIGS. 5, 6A, and 6B) and memory cells in a NAND string arrangement (e.g., portion 900 of memory array 150 in FIGS. 9, 10A, and 10B).

Referring to FIG. 13, fin structure 610/1010 is formed on interlayer dielectric structure 235. This formation can include a deposition of indium gallium zinc oxide or other suitable material (e.g., using an atomic layer deposition process and a physical vapor deposition process) onto interlayer dielectric structure 235 and a fin-cut operation to form fin structure 610/1010. A height H (e.g., in a y direction) of fin structure 610/1010 can be between about 50 nm and about 1000 nm, according to some embodiments.

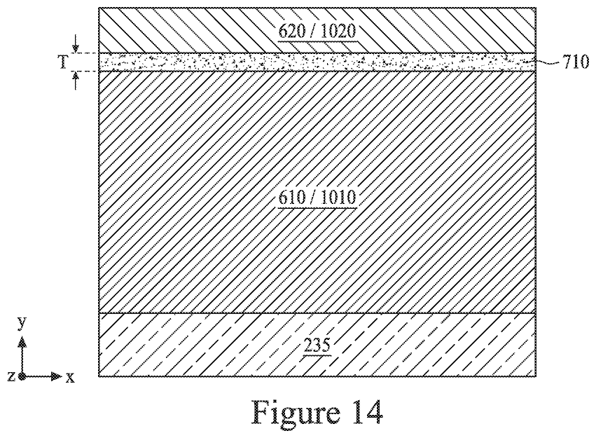

Referring to FIG. 14, ferroelectric material layer 710 and gate structure 620/1020 are deposited on fin structure 610/1010 using, for example, an atomic layer deposition process. In some embodiments, a thickness T of ferroelectric material layer 710 (e.g., hafnium zirconium oxide) along a top surface and side surfaces of fin structure 610/1010 is greater than about 3 nm and has an orthorhombic phase.

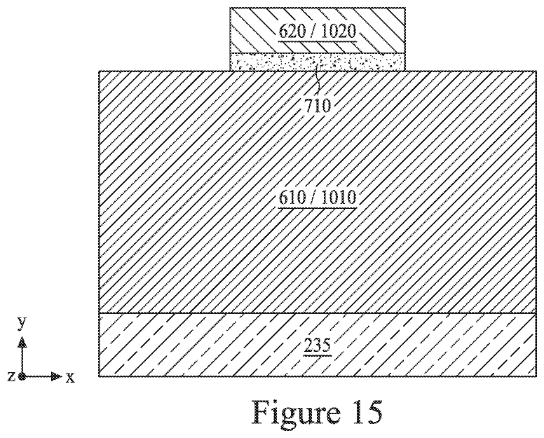

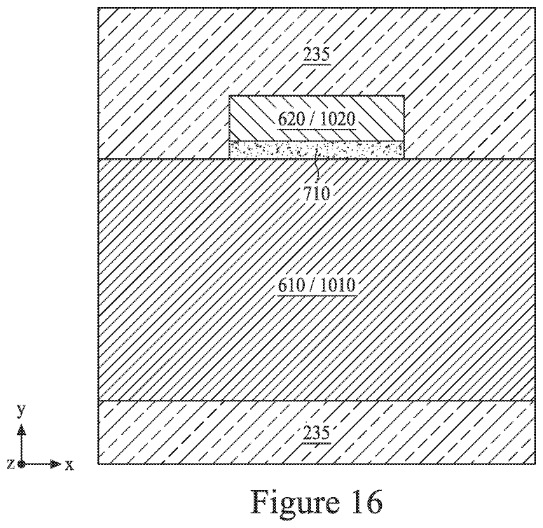

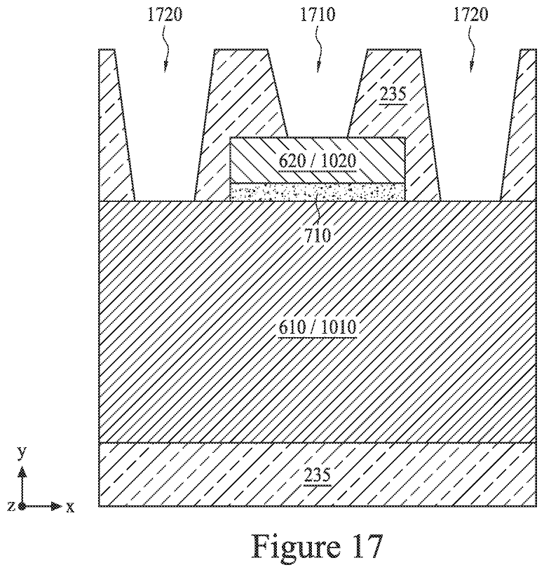

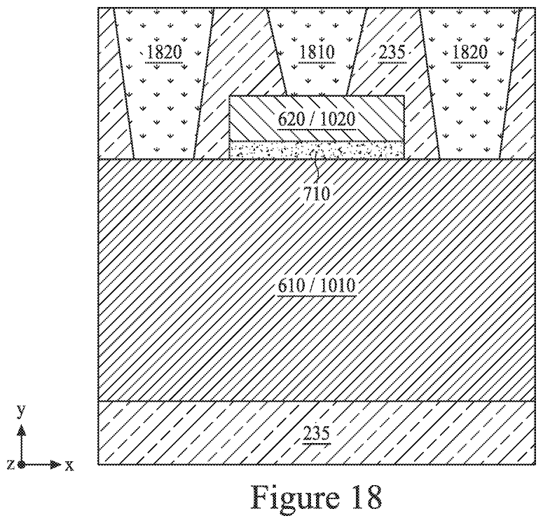

Referring to FIG. 15, a polishing operation (e.g., a chemical mechanical polishing operation) and a cut operation are performed. Referring to FIG. 16, another interlayer dielectric structure 235 is formed on the structure shown in FIG. 15. Referring to FIG. 17, a gate terminal opening 1710 and source/drain terminal openings 1720 are formed by, for example, a photo pattern and etch process. And referring to FIG. 18, gate terminal opening 1710 and source/drain terminal openings 1720 are filled with a conductive material—e.g., Cu, Al, TiN, TaN, W, or other suitable conductive materials—and the resulting filled structures are polished to form a gate contact structure and source/drain contact structures.

The present disclosure describes a semiconductor device (e.g., semiconductor device 200 of FIG. 2) that includes memory devices (e.g., FeRAM cells in memory device region 233 of FIG. 2) in a back end of line region (e.g., second interconnect region 232 of FIG. 2). The semiconductor device can include a substrate, a first interconnect region disposed over the substrate, a second interconnect region disposed over the first interconnect region, and a third interconnect region disposed over the second interconnect region. The substrate (e.g., substrate 210 of FIG. 2) can include electrical components—e.g., active devices, passive devices, or a combination active and passive devices—formed thereon. The first interconnect region (e.g., first interconnect region 231 of FIG. 2) can include interconnect structures (e.g., metal line structures and metal via structures) to electrically connect the electrical components to one another and/or to upper interconnect structures (e.g., interconnect structures in second interconnect region 232 and in third interconnect region 236 of FIG. 2). The second interconnect region can include a memory device region (e.g., memory device region 233 of FIG. 2) and interconnect structures (e.g., metal line structures and metal via structures). The memory device region can include memory cells (e.g., FeRAM cells) electrically connected to the electrical components via the interconnect structures in the first interconnect region. Each of the ferroelectric memory cells can include a ferroelectric material (e.g., ferroelectric material layer 710 of FIGS. 7, 8, and 11) disposed on a top surface and side surfaces of a fin structure (e.g., fin structure 610 of FIGS. 6B, 7, and 8 and fin structure 1010 of FIGS. 10B and 11). Further, the third interconnect region can include interconnect structures (e.g., metal line structures and metal via structures).

A benefit, among others, of implementing the memory cells in the memory device region is that back end of line region of the semiconductor device can be utilized for the fabrication of memory cells, thus increasing storage capacity in the semiconductor device. Another benefit of implementing the memory cells in the back end of line region is that additional substrate area is available for the implementation of additional electrical components to enhance the functionality and performance of the semiconductor device.

Embodiments of the present disclosure include a structure with a first interconnect structure, a second interconnect structure, and a memory device region. The first interconnect region is over a substrate and includes first interconnect structures. The second interconnect region is over the first interconnect region and includes second interconnect structures electrically connected to the first interconnect structures. The memory device region is between the first and second interconnect regions and includes ferroelectric memory cells.

Embodiments of the present disclosure include a semiconductor structure with a substrate, a first interconnect region, a second interconnect region, and a memory device region. The substrate includes one or more electrical components formed thereon. The first interconnect region is over the substrate and includes first interconnect structures electrically connected to the one or more electrical components. The second interconnect region is over the first interconnect region and includes second interconnect structures electrically connected to the first interconnect structures. The memory device region is between the first and second interconnect regions and includes ferroelectric memory cells electrically connected to the one or more electrical components through the first interconnect structures. Each of the ferroelectric memory cells includes a ferroelectric material disposed on a fin structure.

Embodiments of the present disclosure include a method to form a memory cell in a back end of line device memory region of a semiconductor device. The method includes forming one or more electrical components on a substrate. The method also includes: forming, over the substrate, a first interconnect region with first interconnect structures electrically connected to the one or more electrical components; and forming, over the first interconnect region, a second interconnect region with second interconnect structures electrically connected to the first interconnect structures. The method further includes forming a memory device region between the first and second interconnect regions, where the memory device region includes ferroelectric memory cells.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a first interconnect region over a substrate and comprising a first plurality of interconnect structures;
a second interconnect region over the first interconnect region and comprising a second plurality of interconnect structures electrically connected to the first plurality of interconnect structures; and
a memory device region between the first and second interconnect regions, wherein the memory device region comprises a plurality of ferroelectric memory cells.

2. The structure of claim 1, wherein the plurality of ferroelectric memory cells comprise a plurality of ferroelectric random access memory cells, wherein each of the plurality of ferroelectric random access memory cells comprises a ferroelectric material layer having a first protection layer and a second protection layer, and wherein the first and second protection layers have a width between about 1 nm and about 2 nm and a doping of zirconium between about 1% and about 2%.

3. The structure of claim 1, wherein each of the ferroelectric memory cells comprises:
a fin structure comprising an indium-gallium-zinc-oxide material; and
a hafnium zirconium oxide layer disposed on the fin structure.

4. The structure of claim 3, further comprising:
a first protection layer disposed between the fin structure and the hafnium zirconium oxide layer; and
a second protection layer disposed on the hafnium zirconium oxide layer, wherein the first and second protection layers comprise one or more of hafnium oxide, hafnium aluminum oxide, and hafnium silicon oxide.

5. The structure of claim 1, wherein the plurality of ferroelectric memory cells are arranged in a NOR string arrangement of ferroelectric memory cells.

6. The structure of claim 5, wherein the plurality of ferroelectric memory cells comprise a first ferroelectric memory cell and a second ferroelectric memory cell, and wherein the NOR string arrangement of ferroelectric memory cells comprises:
a source/drain (S/D) region of the first ferroelectric memory cell and a S/D region of the second ferroelectric memory electrically connected to a common source line; and
another S/D region of the first ferroelectric memory cells and another S/D region of the second ferroelectric memory cell electrically connected to a bitline.

7. The structure of claim 6, wherein the common source line is electrically connected to ground.

8. The structure of claim 1, wherein the plurality of ferroelectric memory cells are arranged in a NAND string arrangement of ferroelectric memory cells.

9. The structure of claim 8, wherein the plurality of ferroelectric memory cells comprise a first ferroelectric memory cell and a second ferroelectric memory cell, and wherein the NAND string arrangement of ferroelectric memory cells comprises:
a source/drain (S/D) region of the first ferroelectric memory cell electrically connected to a bitline select transistor;
a S/D region of the second ferroelectric memory cell electrically connected to a ground select transistor; and
another S/D region of the first ferroelectric memory cell and another S/D region of the second ferroelectric memory cell electrically connected to one another.

10. The structure of claim 3, wherein the fin structure has a height between about 50 nm and about 1000 nm.

11. A semiconductor structure, comprising:
a substrate comprising one or more electrical components formed thereon;
a first interconnect region over the substrate and comprising a first plurality of interconnect structures electrically connected to the one or more electrical components;
a second interconnect region over the first interconnect region and comprising a second plurality of interconnect structures electrically connected to the first plurality of interconnect structures; and
a memory device region between the first and second interconnect regions, wherein the memory device region comprises a plurality of ferroelectric memory cells electrically connected to the one or more electrical components through the first plurality of interconnect structures, and wherein each of the plurality of ferroelectric memory cells comprises a ferroelectric material disposed on a fin structure.

12. The semiconductor structure of claim 11, further comprising:
a third interconnect region disposed below the plurality of electrical components.

13. The semiconductor structure of claim 11, wherein the one or more electrical components comprise a plurality of active devices, a plurality of passive devices, or a combination thereof.

14. The semiconductor structure of claim 13, wherein the plurality of active devices comprises a fin field effect transistor, a gate all around transistor, a planar field effect transistor, or a combination thereof.

15. The semiconductor structure of claim 11, wherein the substrate comprises a backside interconnect region having interconnect structures arranged to provide a power supply voltage to the one or more electrical components.

16. A method, comprising:
forming one or more electrical components on a substrate;
forming, over the substrate, a first interconnect region with a first plurality of interconnect structures electrically connected to the one or more electrical components;
forming, over the first interconnect region, a second interconnect region with a second plurality of interconnect structures electrically connected to the first plurality of interconnect structures; and
forming a memory device region between the first and second interconnect regions, wherein the memory device region comprises a plurality of ferroelectric memory cells.

17. The method of claim 16, further comprising:
forming a third interconnect structure below the one or more electrical components.

18. The method of claim 16, wherein forming the memory device region comprises forming a plurality of ferroelectric random access memory cells, wherein each of the ferroelectric memory cells comprises:
a fin structure comprising an indium-gallium-zinc-oxide material; and
a hafnium zirconium oxide layer disposed on the fin structure.

19. The method of claim 16, wherein forming the memory device region comprises forming a NOR string arrangement of ferroelectric memory cells, wherein the plurality of ferroelectric memory cells comprise a first ferroelectric memory cell and a second ferroelectric memory cell, and wherein the NOR string of ferroelectric memory cells comprises:
a source/drain (S/D) region of the first ferroelectric memory cell and a S/D region of the second ferroelectric memory electrically connected to a common source line; and
another S/D region of the first ferroelectric memory cells and another S/D region of the second ferroelectric memory cell electrically connected to a bitline.

20. The method of claim 16, wherein forming the memory device region comprises forming a NAND string arrangement of ferroelectric memory cells, wherein the plurality of ferroelectric memory cells comprise a first ferroelectric memory cell and a second ferroelectric memory cell, and wherein the NAND string of ferroelectric memory cells:
a source/drain (S/D) region of the first ferroelectric memory cell electrically connected to a bitline select transistor;
a S/D region of the second ferroelectric memory cell electrically connected to a ground select transistor; and
an other S/D region of the first ferroelectric memory cells and an other S/D region of the second ferroelectric memory cell electrically connected to one another.
